(19) United States
(12) Patent Application Publication
(10) Pub. No.: US 2016/0343979 A1
(43) Pub. Date: Nov. 24, 2016

(54) OLED (ORGANIC LIGHT EMITTING DIODE) PACKAGING METHOD AND OLED PACKAGE STRUCTURE

(71) Applicant: SHENZHEN CHINA STAR OPTOELECTRONICS TECHNOLOGY CO., LTD., Shenzhen, Guangdong (CN)

(72) Inventors: Yawei LIU, Shenzhen City (CN); Wenhui LI, Shenzhen City (CN)

(21) Appl. No.: 14/758,562

(22) PCT Filed: Apr. 1, 2015
(86) PCT No.: PCT/CN2015/075684

§ 371 Date: Jun. 29, 2015

(30) Foreign Application Priority Data
Jan. 22, 2015 (CN) 201510033337.7

(51) Int. Cl. H01L 51/52; H01L 27/32; H01L 51/56

(52) U.S. Cl. CPC H01L 51/5246; H01L 51/56; H01L 51/5253; H01L 27/3244; H01L 2227/323; H01L 2251/303; H01L 2251/301; H01L 2251/558

(57) ABSTRACT

The present invention provides a method of packaging OLED (Organic Light-Emitting Diode) and an OLED packaging structure. The surface of a packaging area at a TFT (Thin Film Transistor) substrate is produced into an uneven rough surface. The contacting area between sealant and the TFT substrate is increased. The adhesion between a packaging cover and the TFT substrate is enhanced. A sealing film is disposed inside the OLED packaging structure to cover OLED devices and to fill out the internal area enclosed by the sealant. The sealing of the OLED packaging structure is improved. Oxygen and moisture permeated into the interior OLED is reduced. The performance of OLED devices is improved. The life span of OLED devices is extended.

### FIELD OF THE INVENTION

The present invention is related to the field of display technology, and more particularly related to a method of packaging OLED (Organic Light Emitting Diode) and an OLED packaging structure.

### BACKGROUND

OLED is an abbreviation of Organic Light Emitting Diode, with self-luminous, high brightness, wide viewing angle, high contrast, flexible, low power consumption, and other features. OLED has gained wide attention, becomes a displaying method for a new generation, and has began to replace traditional LCD (Liquid Crystal Display) displays gradually. OLED has been applied widely in mobile phone screens, computer monitors, full-color televisions. OLED displaying technology is different from traditional LCD technology as a backlight is not needed. A very thin coating of organic materials and glass substrates are used. When a current passes, these organic materials illuminate light. However, because organic materials are easy to react with water vapor or oxygen, as an organic material displaying device, OLED display has strict requirements for packaging and handling.

Main methods for OLED packaging include the following steps or procedures: desiccant packaging, UV (Ultraviolet) sealant packaging (also known as Dam only packaging), UV sealant and filing sealant packaging (also known as Dam & Fill packaging), glass sealant packaging (also known as Frit packaging), and etc. UV sealant packaging technology is the earliest and most commonly used OLED packaging technology with the following characters: no or less solvent is used to reduce the environmental pollution; low energy consumption, low temperature solidification, suitable for UV sensitive materials; high solidification speed, high efficiency, and may be used in high-speed production line; small occupying area for solidification equipments, and etc. However, the sealant used in UV packaging is an organic material. The molecule gapping after solidification is relatively high. When the traditional OLED packaging method is used, because the sealant has solidifying defects, porosity, weak affinity between the substrate and the packaging cover, and other problems, water vapor and oxygen may permeate into the internal sealing area through gapping easily, resulting in a faster degradation of the performances of OLED devices and a shortened life span.

Thus, by packaging OLED more effectively, the sealing of the internal OLED devices is ensured, and the contact of OLED devices with oxygen and water vapor in the outside environment is minimized as much as possible. The effective packaging of OLED is essential for the stability of the performance of OLED devices and for the extension of the life span of OLED.

### BRIEF SUMMARY OF THE INVENTION

The goal of the present invention is to provide a method of packaging OLED. The adhesion between a packaging cover and the TFT substrate is enhanced. Oxygen and moisture permeated into the interior OLED are considerably reduced. The performance of OLED devices is improved. The life span of OLED devices is extended.

Another goal of the present invention is to provide OLED packaging structure. The surface of a packaging area at a TFT (Thin Film Transistor) substrate is produced into an uneven rough surface. The contacting area between sealant and the TFT substrate is increased. The adhesion between a packaging cover and the TFT substrate is enhanced. In the mean time, a sealing film is applied to cover and protect OLED devices. Oxygen and moisture permeated into the interior OLED are considerably reduced. The performance of OLED devices is improved. The life span of OLED devices is extended.

The present invention provides a method of packaging an OLED, including the following steps.

In Step 1, a TFT substrate is provided;

The TFT substrate includes a displaying area, and a packaging area surrounding the displaying area. The structure of the TFT substrate at the packaging area includes a substrate, a metal layer formed on the substrate, a gate electrode insulating layer formed on the metal layer covering the metal layer and the substrate, an etch stopping layer formed on the gate electrode insulating layer, and a passivation layer formed on the etch stopping layer;

In Step 2, the surface of the TFT substrate located at the packaging area is produced into a rough surface;

In Step 3, OLED devices on the displaying area of the TFT substrate are produced;

In Step 4, a package cover is provided, and sealant is applied on the package cover corresponding to the packaging area of the TFT substrate;

In Step 5, a layer of sealing film is pasted on an internal region of the package cover surrounded by the sealant;

In Step 6, the TFT substrate is bound with the package cover correspondingly;

In Step 7, the sealant is solidified by irradiating the sealant with UV light, so as to complete the packaging of the package cover on the TFT substrate.

An embodiment of Step 2 includes: applying a photo-resist layer on the surface of the passivation layer located at the packaging area, forming a plurality of spaced channels on the photo-resist layer by light mask exposure, and developing processes.

The thickness of the photo-resist layer and the depth of the channels is 0˜50 μm.

Another embodiment of Step 2 includes: applying a photo-resist layer on the surface of the passivation layer located at the packaging area, forming a plurality of spaced grooves on the passivation layer and the etch stopping layer by light mask exposure, developing, etching, and photo-resist removing processes, wherein the grooves penetrate the passivation layer but do not penetrate the etch stopping layer.

The depth of the grooves is 0˜50 μm.

Another embodiment of Step includes: forming an inorganic layer with a rough surface on the passivation layer by a chemical vapor deposition method.

The material of the inorganic layer is silicon nitride or silicon dioxide.

The thickness of the sealing film at Step 5 is 0˜100 um.

The thickness of the sealing film at Step 5 is 20 um.

The present invention also provides a method of packaging an OLED, including the following steps.

In Step 1, a TFT substrate is provided;

The TFT substrate includes a displaying area, and a packaging area surrounding the displaying area. The structure of the TFT substrate at the packaging area includes a substrate, a metal layer formed on the substrate, a gate electrode insulating layer formed on the metal layer covering the metal layer and the substrate, an etch stopping layer formed on the gate electrode insulating layer, and a passivation layer formed on the etch stopping layer.

In Step 2, the surface of the TFT substrate located at the packaging area is produced into a rough surface;

In Step 3, OLED devices on the displaying area of the TFT substrate are produced;

In Step 4, a package cover is provided, and sealant is applied on the package cover corresponding to the packaging area of the TFT substrate;

In Step 5, a layer of sealing film is pasted on an internal region of the package cover surrounded by the sealant;

In Step 6, the TFT substrate is bound with the package cover correspondingly;

In Step 7, the sealant is solidified by irradiating the sealant with UV light, so as to complete the packaging of the package cover on the TFT substrate;

An embodiment of Step 2 includes: applying a photo-resist layer on the surface of the passivation layer located at the packaging area, forming a plurality of spaced channels on the photo-resist layer by light mask exposure, and developing processes;

The thickness of the sealing film at Step 5 is 0˜100 um.

The present invention also provides an OLED packaging structure, including a TFT substrate, a package cover corresponding the TFT substrate, OLED devices located on a displaying area in the middle of the TFT substrate, sealant located between a packaging area surrounding the edges of the TFT substrate and a corresponding area on the package cover, a sealing film covering all OLED devices and filling out the internal area enclosed by the sealant between the TFT substrate and the package cover completely, wherein the surface of the packaging area surrounding the edges of the TFT substrate is an uneven rough surface.

The efficacy of the present invention is: the present invention provides a method of packaging OLED (Organic Light-Emitting Diode) and an OLED packaging structure. The surface of a packaging area at a TFT (Thin Film Transistor) substrate is produced into an uneven rough surface. The contacting area between sealant and the TFT substrate is increased. The adhesion between a packaging cover and the TFT substrate is enhanced. A sealing film is disposed inside the OLED packaging structure to cover OLED devices and to fill out the internal area enclosed by the sealant. The sealing of the OLED packaging structure is improved. Oxygen and moisture permeated into the interior OLED is reduced. The performance of OLED devices is improved. The life span of OLED devices is extended.

In order to understand the present invention further, please refer to the following detailed description of the present invention. The drawings are only intended to provide references for illustration, not intended to limit the scope of the present invention.

### BRIEF DESCRIPTION OF THE DRAWINGS

A brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 depicts a flowchart of a method of packaging OLED of the present invention;

FIG. 2 depicts a schematic cross-sectional view of a TFT substrate provided by the Step 1 of the method of packaging OLED of present invention;

FIG. 3 depicts a schematic view of the first embodiment of the Step 2 of the method of packaging OLED of the present invention;

FIG. 4 depicts a schematic view of an etching processing of the embodiment of the Step 2 of the method of packaging OLED of the present invention;

FIG. 5 depicts a schematic view of a photo-resist removing process of the embodiment of the Step 2 of the method of packaging OLED of the present invention;

FIG. 6 depicts a schematic view of the third embodiment of the Step 2 of method of packaging OLED of the present invention;

FIG. 7 depicts a schematic view of the Step 3 of the method of packaging OLED of the present invention;

FIG. 8 depicts a schematic view of the Step 4 of the method of packaging OLED of the present invention;

FIG. 9 depicts a schematic view of the Step 5 of the method of packaging OLED of the present invention;

FIG. 10 depicts a schematic view of the Step 6 of the method of packaging OLED of the present invention;

FIG. 11 depicts a schematic view of the Step 7 of the method of packaging OLED of the present invention. Reference will now be made in detail to exemplary embodiments of the invention, which are illustrated in the accompanying drawings.

### DETAILED DESCRIPTION

For better explaining the technical solution and the effect of the present invention, the present invention will be further described in detail with the accompanying drawings and the specific embodiments.

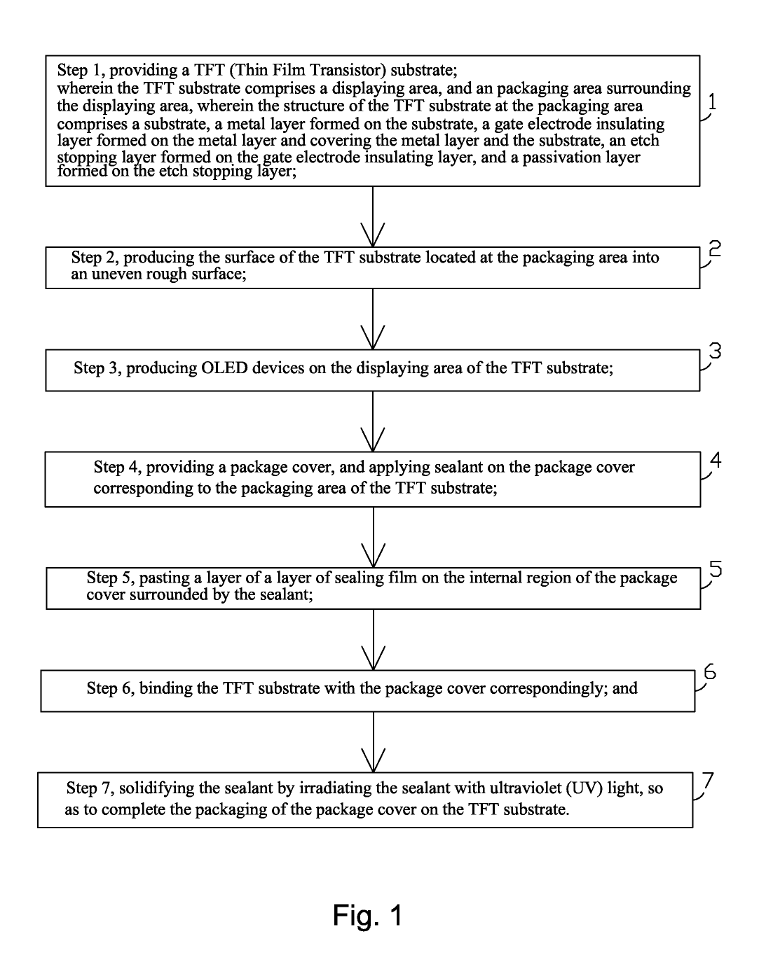

FIG. 1 depicts a method of packaging OLED, including the following steps:

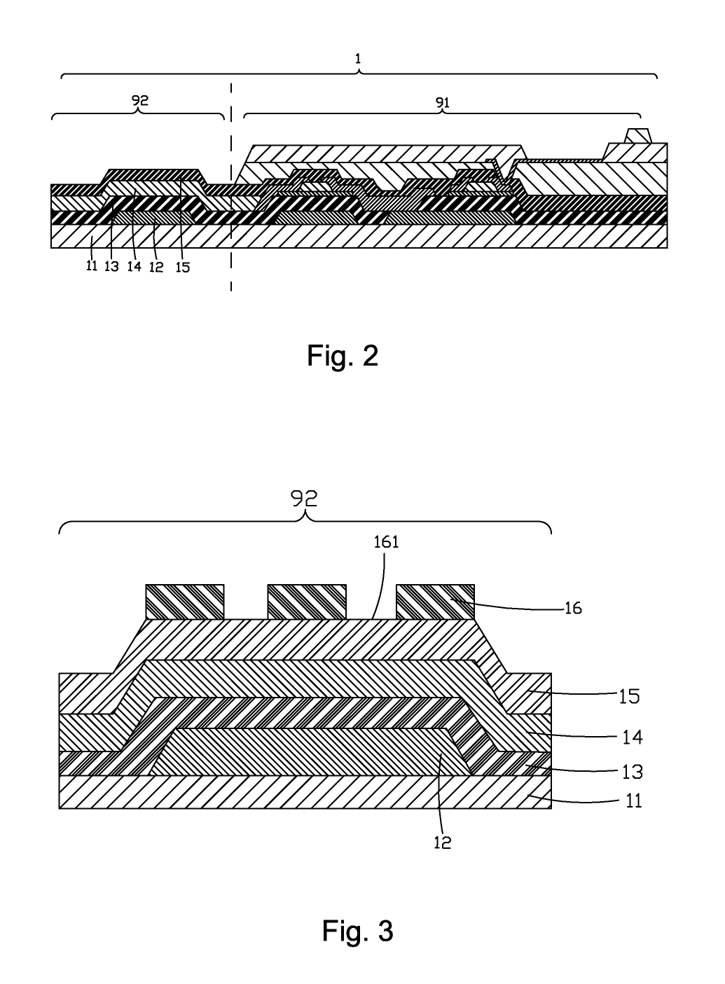

In Step 1, as shown in FIG. 2, a TFT substrate is provided.

More specifically, the TFT substrate includes a displaying area 91, and a packaging area 92 surrounding the displaying area 91. The structure of the TFT substrate 1 at the packaging area 92 includes a substrate 11, a metal layer 12 formed on the substrate 11, a gate electrode insulating layer 13 formed on the metal layer 12 and covering the metal layer 12 and the substrate 11, an etch stopping layer 14 formed on the gate electrode insulating layer 13, and a passivation layer 15 formed on the etch stopping layer 14.

In Step 2, the surface of the TFT substrate 1 located at the packaging area 92 is produced into an uneven rough surface.

More specifically, the Step 2 may be achieved by the following 3 embodiments:

### In Embodiment 1

As shown in FIG. 3, a photo-resist layer 16 is applied on the surface of the passivation layer 15 located at the packaging area 92. A plurality of spaced channels 161 is formed on the photo-resist layer 16 by light mask exposure, and developing processes. Such that the surface of the photo-resist layer 16 becomes uneven. During the following packaging process, the contacting area between the sealant 4 and the surface of the substrate TFT 1 is increased, and the adhesion between the packaging cover 2 and the TFT substrate 1 is increased;

Specifically, the thickness of the photo-resist layer 16 and the depth of the channels 161 is 0˜50 μm.

### In Embodiment 2

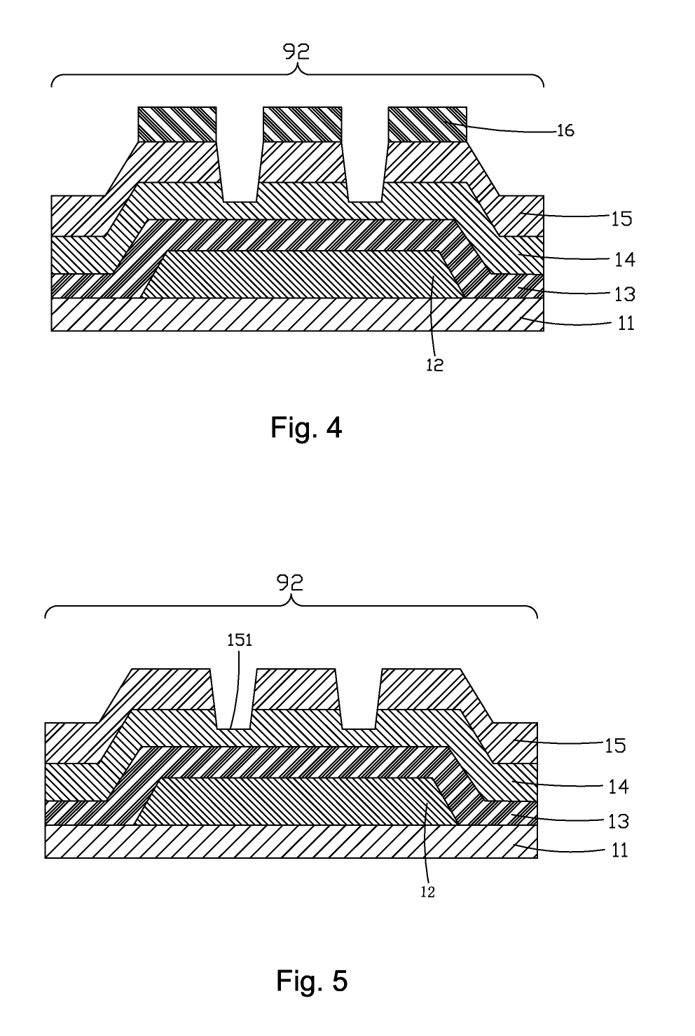

As shown in FIG. 4-5, a photo-resist layer 16 is applied on the surface of the passivation layer 15 located at the packaging area 92, forming a plurality of spaced grooves 151 on the passivation layer 15 and the etch stopping layer 14 by light mask exposure, developing, etching, and photo-resist removing processes. The grooves 151 penetrate the passivation layer 15 but do not penetrate the etch stopping layer 14. Such that an uneven surfaced is formed on the passivation layer 15 and the etch stopping layer 14. During the following packaging process, the contacting area between the sealant 4 and the surface of the substrate TFT 1 is increased, and the adhesion between the packaging cover 2 and the TFT substrate 1 is increased;

Specifically, the depth of the grooves 151 is 0˜50 μm.

### In Embodiment 3

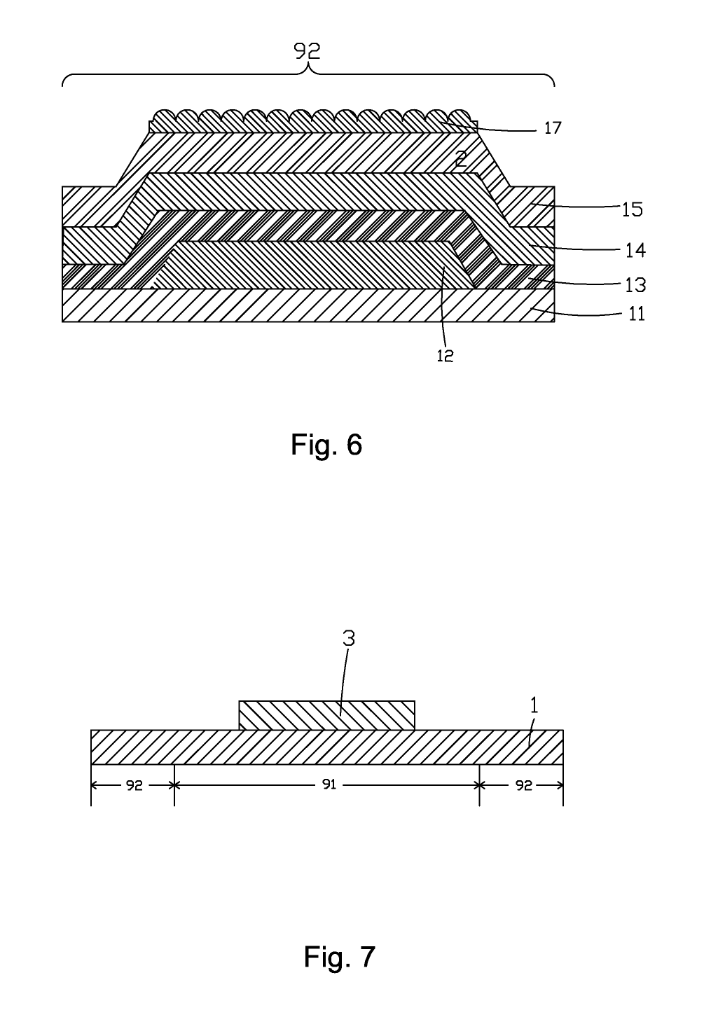

As shown in FIG. 6, the chemical vapor deposition (CVD) technique is applied by controlling the temperature, the voltage, and other parameters of CVD. An inorganic layer 17 is formed with a rough surface on the passivation layer 15 located at the packaging area 92, such that the surface of the packaging area of the TFT substrate 1 becomes uneven. During the following packaging process, the contacting area between the sealant 4 and the surface of the substrate TFT 1 is increased, and the adhesion between the packaging cover 2 and the TFT substrate 1 is increased;

Preferably, the material of the inorganic layer 17 is silicon nitride or silicon dioxide.

In Step 3, as shown in FIG. 7, OLED devices 3 are produced on the displaying area 91 of the TFT substrate 1.

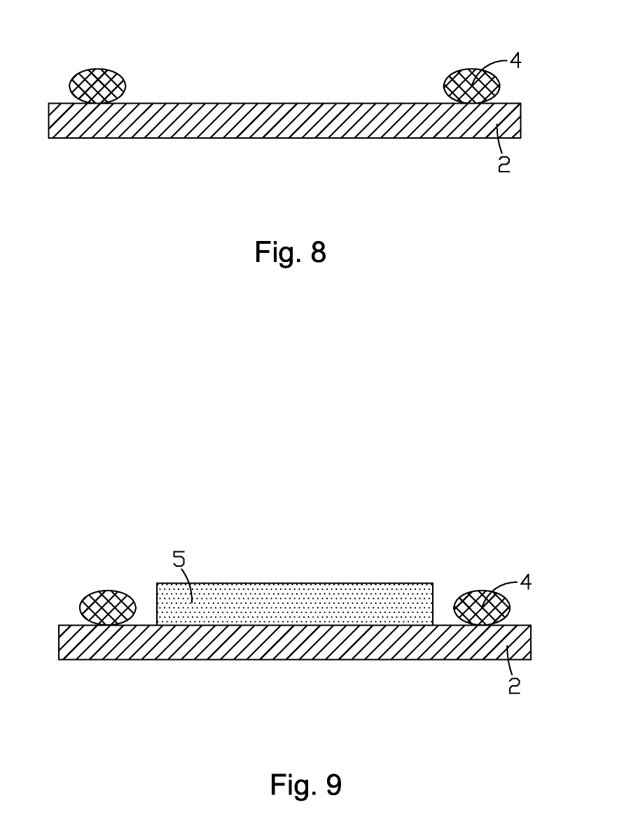

In Step 4, as shown in FIG. 8, a package cover is provided. Sealant 4 is applied on the package cover 2 corresponding to the packaging area 92 of the TFT substrate 1.

In Step 5, as shown in FIG. 9, a layer of sealing film 5 is pasted on the internal region of the package cover 2 surrounded by the sealant 4.

The sealing film 5 may absorb water vapor permeated into the sealant 4, and prolong the life span of OLED. The thickness of the sealing film is 0˜100 um. Preferably, the thickness of the sealing film is 20 um.

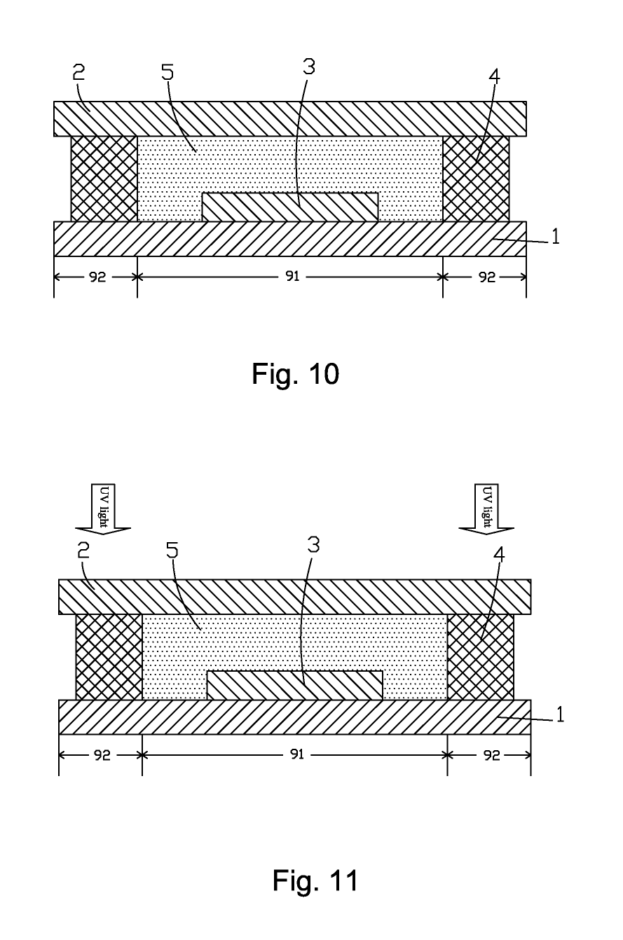

In Step 6, as shown in FIG. 10, the TFT substrate 1 is bound with the package cover 2 correspondingly.

Specifically, the after the TFT substrate 1 is bound with the package cover 2 correspondingly, the sealing film 5 covers the OLED devices 3 completely. The sealing film 5 fills out the internal space enclosed by the sealant 4 between the TFT substrate 1 and the packaging cover 2. The sealing of OLED is improved effectively.

In Step 7, as shown in FIG. 11, the sealant is solidified by irradiating the sealant with UV light, so as to complete the packaging of the package cover on the TFT substrate.

Based on the above packaging method, in reference of FIG. 11, the present invention also provides an OLED packaging structure, including a TFT substrate 1, a package cover 2 corresponding the TFT substrate 1, OLED devices 3 located on a displaying area 91 in the middle of the TFT substrate 1, sealant 4 located between a packaging area 92 surrounding the edges of the TFT substrate 1 and a corresponding area on the package cover 2, a sealing film 5 covering all OLED devices and filling out the internal area enclosed by the sealant 4 between the TFT substrate 1 and the package cover 2 completely. The surface of the packaging area 92 of the TFT substrate 1 is an uneven rough surface.

Specifically, in reference of FIG. 3, the structure of TFT substrate 1 located at the packaging area 92 may includes: a substrate 11, a metal layer 12 formed on the substrate 11, a gate electrode insulating layer 13 formed on the metal layer 12 and covering the metal layer 12 and the substrate 11, an etch stopping layer 14 formed on the gate electrode insulating layer 13, a passivation layer 15 formed on the etch stopping layer 14, and a photo-resist layer 16 formed on the passivation layer 15. A plurality of spaced channels 161 is on the photo-resist layer 16. Specifically, the thickness of the photo-resist layer 16, i.e. the depth of the channels 161, is 0-50 um.

Optionally, in reference of FIG. 5, the structure of TFT substrate 1 located at the packaging area 92 may includes: a substrate 11, a metal layer 12 formed on the substrate 11, a gate electrode insulating layer 13 formed on the metal layer 12 and covering the metal layer 12 and the substrate 11, an etch stopping layer 14 formed on the gate electrode insulating layer 13, and a passivation layer 15 formed on the etch stopping layer 14. A plurality of spaced grooves 151 is formed on the passivation layer 15 and the etch stopping layer 14. The grooves 15 penetrate the passivation layer 15, but do not penetrate the etch stopping layer 14. Specifically, the depth of the grooves 151 is 0-50 um.

Optionally, in reference of FIG. 6, the structure of TFT substrate 1 located at the packaging area 92 may includes: a substrate 11, a metal layer 12 formed on the substrate 11, a gate electrode insulating layer 13 formed on the metal layer 12 and covering the metal layer 12 and the substrate 11, an etch stopping layer 14 formed on the gate electrode insulating layer 13, a passivation layer 15 formed on the etch stopping layer 14, and a rough inorganic layer 17 formed on the passivation layer 15. Preferably, the material of the inorganic layer 17 is SiNx (silicon nitride) or SiO2 (silicon dioxide).

Specifically, the thickness of the sealing film 5 is 0˜100 um. Preferably, the thickness of the sealing film 5 is 20 um.

Thus, the present invention provides a method of packaging OLED (Organic Light-Emitting Diode) and an OLED packaging structure. The surface of a packaging area at a TFT (Thin Film Transistor) substrate is produced into an uneven rough surface. The contacting area between sealant and the TFT substrate is increased. The adhesion between a packaging cover and the TFT substrate is enhanced. A sealing film is disposed inside the OLED packaging structure to cover OLED devices and to fill out the internal area enclosed by the sealant. The sealing of the OLED packaging structure is improved. Oxygen and moisture permeated into the interior OLED is reduced. The performance of OLED devices is improved. The life span of OLED devices is extended.

Embodiments of the present invention have been described, but not intending to impose any unduly constraint to the appended claims. Any modification of equivalent structure or equivalent process made according to the invention and drawings of the present invention, or any application thereof, directly or indirectly, to other related fields of technique, is considered encompassed in the scope of protection defined by the claims of the present invention.

What is claimed is:

1. A method of packaging an OLED (Organic Light Emitting Diode), comprising:
Step 1, providing a TFT (Thin Film Transistor) substrate,
wherein the TFT substrate comprises a displaying area, and an packaging area surrounding the displaying area, wherein the structure of the TFT substrate at the packaging area comprises a substrate, a metal layer formed on the substrate, a gate electrode insulating layer formed on the metal layer and covering the metal layer and the substrate, an etch stopping layer formed on the gate electrode insulating layer, and a passivation layer formed on the etch stopping layer;
Step 2, producing the surface of the TFT substrate located at the packaging area into an uneven rough surface;
Step 3, producing OLED devices on the displaying area of the TFT substrate;
Step 4, providing a package cover, and applying sealant on the package cover corresponding to the packaging area of the TFT substrate;
Step 5, pasting a layer of a layer of sealing film on the internal region of the package cover surrounded by the sealant;
Step 6, binding the TFT substrate with the package cover correspondingly;
Step 7, solidifying the sealant by irradiating the sealant with ultraviolet (UV) light, so as to complete the packaging of the package cover on the TFT substrate.

2. The method of packaging the OLED according to claim 1, wherein the Step 2 comprises: applying a photo-resist layer on the surface of the passivation layer located at the packaging area, forming a plurality of spaced channels on the photo-resist layer by light mask exposure, and developing processes.

3. The method of packaging the OLED according to claim 2, wherein the thickness of the photo-resist layer and the depth of the channels is 0-50 um.

4. The method of packaging the OLED according to claim 1, wherein the Step 2 comprises: applying a photo-resist layer on the surface of the passivation layer located at the packaging area, forming a plurality of spaced grooves on the passivation layer and the etch stopping layer by light mask exposure, developing, etching, and photo-resist removing processes, wherein the grooves penetrate the passivation layer but do not penetrate the etch stopping layer.

5. The method of packaging the OLED according to claim 4, wherein the depth of the grooves is 0˜50 μm.

6. The method of packaging the OLED according to claim 1, wherein the Step 2 comprises: forming an inorganic layer with a rough surface on the passivation layer by a chemical vapor deposition method.

7. The method of packaging the OLED according to claim 6, wherein the material of the inorganic layer is silicon nitride or silicon dioxide.

8. The method of packaging the OLED according to claim 1, wherein the thickness of the sealing film at Step 5 is 0˜100 um.

9. The method of packaging the OLED according to claim 8, wherein the thickness of the sealing film at Step 5 is 20 um.

10. A method of packaging an OLED, comprising:
Step 1, providing a TFT substrate,
wherein the TFT substrate comprises a displaying area, and an packaging area surrounding the displaying area, wherein the structure of the TFT substrate at the packaging area comprises a substrate, a metal layer formed on the substrate, a gate electrode insulating layer formed on the metal layer covering the metal layer and the substrate, an etch stopping layer formed on the gate electrode insulating layer, and a passivation layer formed on the etch stopping layer;
Step 2, producing the surface of the TFT substrate located at the packaging area into a rough surface;
Step 3, producing OLED devices on the displaying area of the TFT substrate;
Step 4, providing a package cover, and applying sealant on the package cover corresponding to the packaging area of the TFT substrate;
Step 5, pasting a layer of sealing film on an internal region of the package cover surrounded by the sealant;
Step 6, binding the TFT substrate with the package cover correspondingly;
Step 7, solidifying the sealant by irradiating the sealant with UV light, so as to complete the packaging of the package cover on the TFT substrate;
wherein the Step 2 comprises: applying a photo-resist layer on the surface of the passivation layer located at the packaging area, forming a plurality of spaced channels on the photo-resist layer by light mask exposure, and developing processes; and
wherein the thickness of the sealing film at Step 5 is 0˜100 um.

11. The method of packaging the OLED according to claim 10, wherein the thickness of the sealing film at Step 5 is 20 um.

12. The method of packaging the OLED according to claim 10, wherein the thickness of the photo-resist layer and the depth of the channels is 0˜50 μm.

13. An OLED packaging structure, comprising a TFT substrate, a package cover corresponding the TFT substrate, OLED devices located on a displaying area in the middle of the TFT substrate, sealant located between a packaging area surrounding the edges of the TFT substrate and a corresponding area on the package cover, a sealing film covering all OLED devices and filling out the internal area enclosed by the sealant between the TFT substrate and the package cover completely, wherein the surface of the packaging area surrounding the edges of the TFT substrate is an uneven rough surface.
